(19) United States
(12) Patent Application Publication
(10) Pub. No.: US 2024/0204062 A1
(43) Pub. Date: Jun. 20, 2024

(54) SEMICONDUCTOR DEVICE

(71) Applicant: ROHM CO., LTD., Kyoto (JP)

(72) Inventors: Chikara TERADA, Kyoto (JP); Shusaku FUJIE, Kyoto (JP)

(73) Assignee: ROHM CO., LTD., Kyoto (JP)

(21) Appl. No.: 18/592,203

(22) Filed: Feb. 29, 2024

Related U.S. Application Data
(63) Continuation of application No. PCT/JP2022/031398, filed on Aug. 19, 2022.

(30) Foreign Application Priority Data
Sep. 8, 2021 (JP) 2021-146137

(51) Int. Cl. H01L 29/40; H01L 29/08; H01L 29/78

(52) U.S. Cl. CPC H01L 29/405; H01L 29/0869; H01L 29/0886; H01L 29/7816

(57) ABSTRACT

A semiconductor device includes a chip having a main surface, a first conductivity type drain region formed in a surficial portion of the main surface, a first conductivity type source region formed in a region differing from the drain region in the surficial portion of the main surface, a second conductivity type back gate region formed in a region differing from the drain region and from the source region in the surficial portion of the main surface so as to be electrically separated from the drain region and from the source region, a gate insulation film covering the source region on the main surface, and a gate electrode formed on the gate insulation film.

### CROSS REFERENCE TO RELATED APPLICATIONS

The present application is a bypass continuation of International Patent Application No. PCT/JP2022/031398, filed on Aug. 19, 2022, which claims priority to Japanese Patent Application No. 2021-146137 filed in the Japan Patent Office on Sep. 8, 2021, the entire disclosure of which is incorporated herein by reference.

### BACKGROUND

### 1. Field of the Disclosure

The present disclosure relates to a semiconductor device.

### 2. Description of the Related Art

US2013075877A1 discloses a semiconductor device including a semiconductor layer, a first electrode, a second electrode, a horizontal element, and a LOCOS oxide-film resistive field plate. The first electrode is formed on a surface of the semiconductor layer. The second electrode is formed on the surface of the semiconductor layer at a distance from the first electrode. The horizontal element is formed in a region between the first electrode and the second electrode in a surficial portion of the surface of the semiconductor layer, and is electrically connected to the first electrode and to the second electrode. A LOCOS oxide film separates parts, each of which is a constituent of the horizontal element, from each other in the surface of the semiconductor layer. The resistive field plate is formed on the LOCOS oxide film.

### BRIEF DESCRIPTION OF THE DRAWINGS

FIG. 1 is a plan view showing a chip of a semiconductor device according to a first embodiment.

FIG. 2 is an enlarged plan view of a region II shown in FIG. 1.

FIG. 3 is a cross-sectional perspective view of a region III shown in FIG. 2.

FIG. 4 is a cross-sectional view of the region III shown in FIG. 2.

FIG. 5 is a circuit diagram showing an electric structure in a transistor region.

FIG. 6 is an enlarged plan view showing a main portion of a semiconductor device according to a second embodiment.

FIG. 7 is a cross-sectional perspective view of region VII shown in FIG. 6.

### DETAILED DESCRIPTION OF THE PREFERRED EMBODIMENTS

Embodiments will be hereinafter described in detail with reference to the accompanying drawings. The accompanying drawings are schematic views, and are not strictly shown, and do not necessarily coincide with each other in scale and the like. Also, the same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

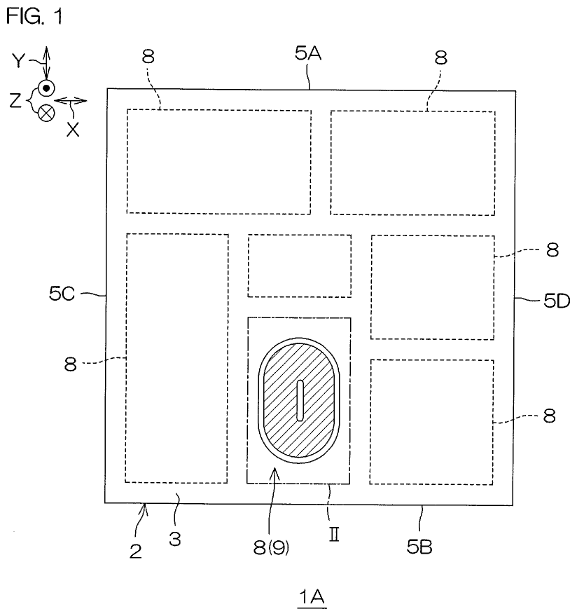

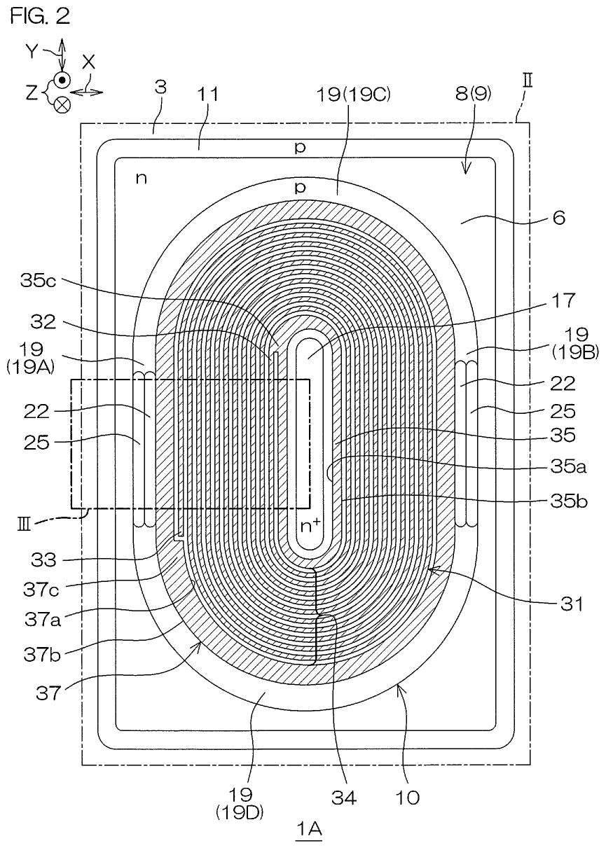

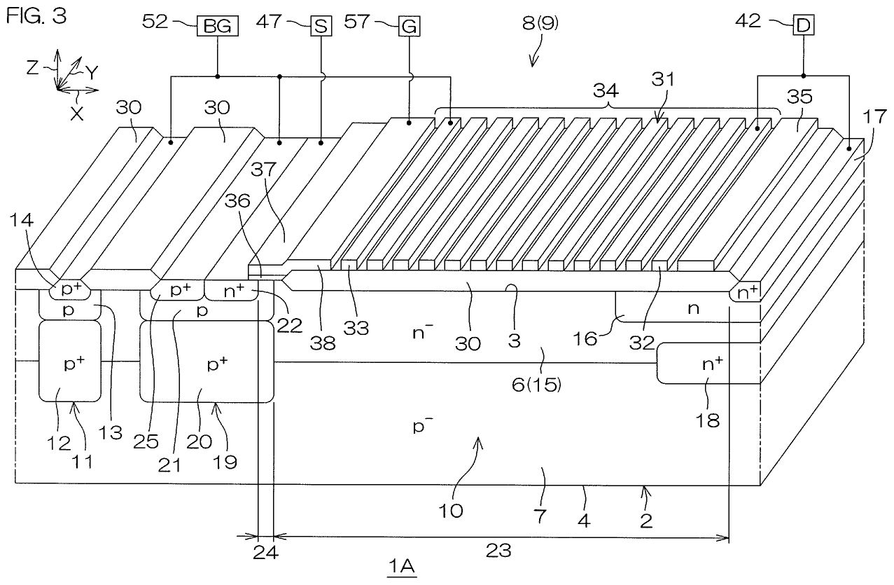

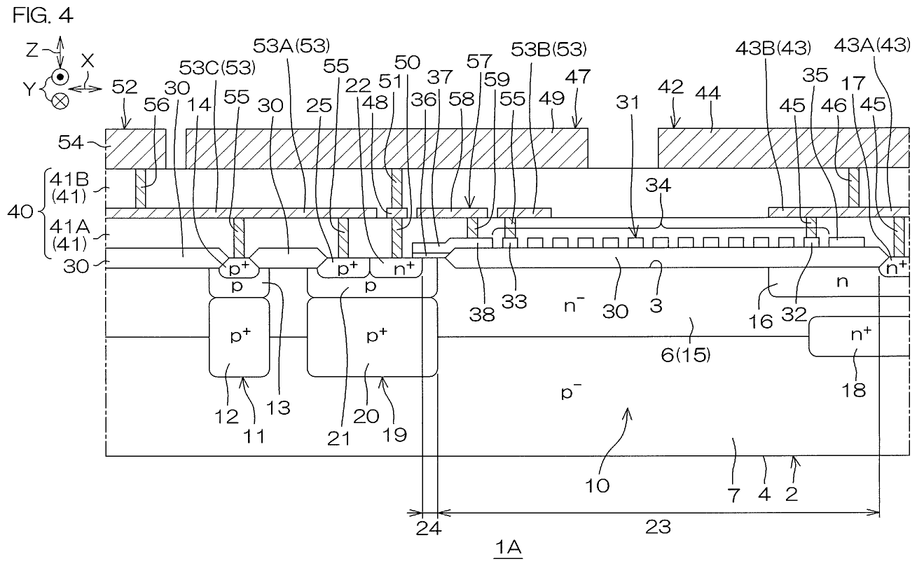

FIG. 1 is a plan view showing a chip 2 of a semiconductor device 1A according to a first embodiment. FIG. 2 is an enlarged view of a region II shown in FIG. 1. FIG. 3 is a cross-sectional perspective view of a region III shown in FIG. 2. FIG. 4 is a cross-sectional view of the region III shown in FIG. 2. Referring to FIG. 1 to FIG. 4, the semiconductor device 1A includes the silicon-made chip 2 (semiconductor chip) formed in a rectangular parallelepiped shape. The chip 2 has a first main surface 3 on one side, a second main surface 4 on the other side, and first to fourth side surfaces 5A to 5D that connect the first main surface 3 and the second main surface 4.

The first main surface 3 and the second main surface 4 are each formed in a quadrangular shape in a plan view seen from their normal directions Z (hereinafter, referred to simply as a “plan view”). The normal direction Z is also a thickness direction of the chip 2. The first side surface 5A and the second side surface 5B extend in a first direction X, and face each other in a second direction Y that intersects the first direction X (in detail, perpendicularly intersects the first direction X). The third side surface 5C and the fourth side surface 5D extend in the second direction Y, and face each other in the first direction X.

The semiconductor device 1A includes an n-type (first conductivity type) first semiconductor region 6 formed in a region on the first main surface 3 side in the chip 2. The first semiconductor region 6 is formed in a layer shape extending along the first main surface 3, and is exposed from the first main surface 3 and from the first to fourth side surfaces 5A to 5D. The thickness of the first semiconductor region 6 may be not less than 5 μm and not more than 20 μm. In this embodiment, the first semiconductor region 6 is formed by an n-type epitaxial layer.

The semiconductor device 1A includes a p-type (second conductivity type) second semiconductor region 7 formed in a region on the second principal surface 4 side in the chip 2. The second semiconductor region 7 is fixed at a back gate potential. The back gate potential may be a reference potential serving as a criterion for a circuit operation, a ground potential, or a potential other than these potentials. The second semiconductor region 7 is formed in a layer shape extending along the second main surface 4, and is exposed from the second main surface 4 and from the first to fourth side surfaces 5A to 5D.

The second semiconductor region 7 is connected to the first semiconductor region 6 inside the chip 2. The thickness of the second semiconductor region 7 may be not less than 50 μm and not more than 400 μm. In this embodiment, the second semiconductor region 7 is formed by a p-type semiconductor substrate. In other words, the chip 2 has a laminated structure including a semiconductor substrate and an epitaxial layer, and includes the first semiconductor region 6 formed in the epitaxial layer and the second semiconductor region 7 formed in the semiconductor substrate.

The semiconductor device 1A includes a plurality of device regions 8 that are divisionally formed in the first main surface 3. The number and the arrangement of the device regions 8 are arbitrary. The device regions 8 each include a functional device formed by use of regions inside and outside the chip 2. The functional device may include at least one among a semiconductor switching device, a semiconductor rectifying device, and a passive device. The functional device may include a circuit network in which at least two among the semiconductor switching device, the semiconductor rectifying device, and the passive device are combined together.

The semiconductor switching device may include at least one among MISFET (Metal Insulator Semiconductor Field Effect Transistor), BJT (Bipolar Junction Transistor), IGBT (Insulated Gate Bipolar Junction Transistor), and JFET (Junction Field Effect Transistor).

The semiconductor rectifying device may include at least one among a pn junction diode, a pin junction diode, a Zener diode, a Schottky barrier diode, and a fast recovery diode. The passive device may include at least one among a resistor, a capacitor, an inductor, and a fuse.

The device regions 8 include at least one (in this embodiment, one) transistor region 9 (see the region II of FIG. 1). The transistor region 9 includes a FET structure 10 (transistor structure). In this embodiment, the FET structure 10 has a so-called LDMISFET (Lateral Double diffused MISFET) structure. In this embodiment, the FET structure 10 consists of a high withstand voltage device to which a drain voltage equal to or more than 800 V in an OFF state can be applied. A structure on the transistor region 9 side will be hereinafter described in detail.

Referring to FIG. 2 to FIG. 4, the semiconductor device 1A includes a p-type separation region 11 that is an example of a region separation structure that divisionally forms the transistor region 9 in the first main surface 3. The separation region 11 is formed in an annular shape surrounding a part of the first main surface 3 in a plan view, and divisionally forms the transistor region 9 having a predetermined shape. The separation region 11 electrically separates the transistor region 9 from other regions (device regions 8).

In this embodiment, the separation region 11 is formed in a quadrangular annular shape (in detail, rectangular annular shape extending in the second direction Y) in a plan view, and divisionally forms the transistor region 9 having a quadrangular shape (in detail, having a rectangular shape extending in the second direction Y) by means of an inner edge of the separation region 11. The planar shape of the separation region 11 (planar shape of the transistor region 9) is arbitrary. The separation region 11 extends from the first main surface 3 toward the second semiconductor region 7 in a wall shape so as to cross the first semiconductor region 6, and is electrically connected to the second semiconductor region 7. In other words, the separation region 11 is fixed at a back gate potential.

In this embodiment, the separation region 11 includes a first separation region 12, a second separation region 13, and a third separation region 14. The first separation region 12 is formed in a boundary portion between the first semiconductor region 6 and the second semiconductor region 7. The first separation region 12 is formed at a distance from the first and second main surfaces 3 and 4 with respect to the normal direction Z, and is electrically connected to the second semiconductor region 7. The first separation region 12 has a p-type impurity concentration higher than the second semiconductor region 7.

The second separation region 13 is formed in a region between the first main surface 3 and the first separation region 12 in the first semiconductor region 6, and is electrically connected to the first separation region 12. The second separation region 13 may have a p-type impurity concentration lower than the first separation region 12. The third separation region 14 is formed in a surficial portion of the second separation region 13, and is exposed from the first main surface 3. The third separation region 14 may have a p-type impurity concentration higher than the second separation region 13.

Referring to FIG. 2 to FIG. 4, the semiconductor device 1A includes an n-type impurity region 15 formed in a surficial portion of the first main surface 3 in the transistor region 9. In this embodiment, the impurity region 15 is formed by use of a part, which is divisionally formed by the separation region 11, of the first semiconductor region 6. Therefore, the impurity region 15 has an n-type impurity concentration equal to an n-type impurity concentration of the first semiconductor region 6.

The semiconductor device 1A includes an n-type well region 16 formed in a surficial portion of the impurity region 15. The well region 16 is fixed at a drain potential. The well region 16 is formed in an inward portion of the impurity region 15. The well region 16 has an n-type impurity concentration higher than the impurity region 15. In this embodiment, the well region 16 is formed in an oval shape extending along the impurity region 15 in a plan view. The well region 16 may be formed in a circular shape, an elliptical shape, or a polygonal shape (for example, quadrangular shape) in a plan view.

The semiconductor device 1A includes an n-type drain region 17 formed in a surficial portion of the well region 16. The drain region 17 is fixed at a drain potential. The drain region 17 has an n-type impurity concentration higher than the well region 16. The drain region 17 is formed in an inward portion of the well region 16 at a distance from a peripheral edge of the well region 16. In this embodiment, the drain region 17 is formed in an oval shape extending along the well region 16 in a plan view. The drain region 17 may be formed in a circular shape, an elliptical shape, or a polygonal shape (for example, quadrangular shape) in a plan view.

The semiconductor device 1A includes an n-type embedded region 18 formed inside the chip 2 so as to cross the bottom portion of the impurity region 15. In detail, the embedded region 18 is formed in a boundary portion between the second semiconductor region 7 and the impurity region 15 below the well region 16. The embedded region 18 has an n-type impurity concentration higher than the impurity region 15. Preferably, the embedded region 18 has an n-type impurity concentration higher than the well region 16.

The embedded region 18 is formed at a distance from a bottom portion of the well region 16 in the normal direction Z, and faces the well region 16 across a part of the impurity region 15. Preferably, the embedded region 18 is formed at a distance inwardly from the peripheral edge of the well region 16 in a plan view. Preferably, the embedded region 18 has an area less than that of the well region 16 in a plan view.

The semiconductor device 1A includes a p-type body region 19 formed in the surficial portion of the first main surface 3 at a distance from the well region 16 in the transistor region 9. In this embodiment, the body region 19 extends from the first main surface 3 toward the second semiconductor region 7 in a wall shape so as to cross the impurity region 15, and is electrically connected to the second semiconductor region 7. In other words, the body region 19 is fixed at a back gate potential.

In this embodiment, the body region 19 includes a first body region 20 and a second body region 21. The first body region 20 is formed in the boundary portion between the second semiconductor region 7 and the impurity region 15. The first body region 20 is formed at a distance from the first and second main surfaces 3 and 4 in the normal direction Z, and is electrically connected to the second semiconductor region 7. The first body region 20 has a p-type impurity concentration higher than the second semiconductor region 7.

The second body region 21 is formed in a region between the first main surface 3 and the first body region 20, and is electrically connected to the first body region 20. The second body region 21 is exposed from the first main surface 3. The second body region 21 has a p-type impurity concentration lower than the first body region 20.

In this embodiment, the body region 19 is formed in an annular shape (in this embodiment, oval annular shape) surrounding the drain region 17 (well region 16) in a plan view, and has its parts extending in the first direction X and its parts extending in the second direction Y. In detail, the body region 19 includes a first region 19A, a second region 19B, a third region 19C, and a fourth region 19D in a plan view. The first to fourth regions 19A to 19D of the body region 19 are formed by the first and second body regions 20 and 21.

The first region 19A is a part that extends in the second direction Y in a belt shape at a distance from the drain region 17 (well region 16) toward one side in the first direction X in a plan view. The second region 19B is a part that extends in the second direction Y in a belt shape at a distance from the drain region 17 (well region 16) toward the other side in the first direction X in a plan view. The second region 19B extends in parallel with the first region 19A in a plan view, and faces the first region 19A across the drain region 17 (well region 16) in the first direction X. Preferably, the length of the first region 19A and the length of the second region 19B are each equal to or less than the length of the drain region 17 with respect to the second direction Y.

The third region 19C is a part that extends in the first direction X in a belt shape so as to connect an end portion of the first region 19A and an end portion of the second region 19B in a plan view. In this embodiment, the third region 19C extends in a circular-arc belt shape between the end portion of the first region 19A and the end portion of the second region 19B in a plan view. Of course, the third region 19C may be formed in a linear belt shape extending in the first direction X.

The fourth region 19D is a part that extends in the first direction X in a belt shape so as to connect the other end portion of the first region 19A and the other end portion of the second region 19B in a plan view. In this embodiment, the fourth region 19D extends in a circular-arc belt shape between the other end portion of the first region 19A and the other end portion of the second region 19B in a plan view. Of course, the fourth region 19D may be formed in a linear belt shape extending in the first direction X.

The semiconductor device 1A includes at least one n-type source region 22 (in this embodiment, a plurality of n-type source regions 22) formed in the surficial portion of the first main surface 3 at a distance from the drain region 17. The source regions 22 are fixed at a source potential. In detail, the source regions 22 are each formed so that a source potential is individually applied to the source regions 22 from the outside of the chip 2 and, as a result, each of the source regions 22 is fixed at this source potential.

In other words, the source potential is given to the source regions 22 independently of a back gate potential. The source potential may be a reference potential, a ground potential, or a potential other than these potentials. The source region 22 has an n-type impurity concentration higher than the well region 16. Preferably, the n-type impurity concentration of the source region 22 is equal to an n-type impurity concentration of the drain region 17.

In detail, the source regions 22 are each formed in a surficial portion of the body region 19 at a distance inwardly from a peripheral edge of the body region 19. In this embodiment, the source regions 22 are each formed in an ended belt shape in a region of a part of the body region 19 in a plan view. In detail, the source regions 22 are formed in a surficial portion of the first region 19A and a surficial portion of the second region 19B, respectively, and are not formed in the third region 19C and in the fourth region 19D. The source regions 22 each extend in an ended belt shape along the first and second regions 19A and 19B in a plan view.

The source regions 22 face the drain region 17 in the first direction X. Preferably, the length of each of the source regions 22 is equal to or less than the length of the drain region 17 with respect to the second direction Y. Of course, the single source region 22 having an annular shape (in detail, oval annular shape) surrounding the impurity region 15 may be formed. Also, the single or more source regions 22 may be formed in at least one region among the first region 19A, the second region 19B, the third region 19C, and the fourth region 19D of the body region 19.

The semiconductor device 1A includes an n-type drift region 23 formed in a region on the drain region 17 side between the drain region 17 and the source region 22 in the surficial portion of the first main surface 3. In detail, the drift region 23 is formed in a region between the drain region 17 and the body region 19 in the surficial portion of the impurity region 15, and forms a current path that connects the drain region 17 and the source region 22. The drift region 23 is formed in an annular shape (in this embodiment, oval annular shape) surrounding the drain region 17.

In this embodiment, the drift region 23 has a first portion (linear portion) that is linearly and divisionally formed and that extends in the second direction Y by means of the first region 19A (second region 19B) of the body region 19 and a second portion (circular arc portion) that is arcedly and divisionally formed by means of the third region 19C (fourth region 19D) of the body region 19. The drift region 23 forms a current path in a part that is along the first region 19A (second region 19B) of the body region 19, and does not form a current path in a part that is along the third region 19C (fourth region 19D) of the body region 19.

The width of the drift region 23 may be not less than 50 μm and not more than 200 μm. The width of the drift region 23 is a distance between the drain region 17 and the body region 19. The width of the drift region 23 may be formed with a substantially constant width along an annular shape (in this embodiment, oval annular shape). The width of the circular arc portion of the drift region 23 may gradually increase from the linear portion toward the middle of the circular arc portion. In this case, the linear portion of the drift region 23 may be formed with a substantially constant width.

The semiconductor device 1A includes a p-type channel region 24 formed in a region on the source region 22 side between the drain region 17 and the source region 22 in the surficial portion of the first main surface 3. In detail, the channel region 24 is formed in a region between the source region 22 and the drift region 23 in the surficial portion of the body region 19. Current passage and non-current passage in the current path between the drain region 17 and the source region 22 are controlled in the channel region 24.

The semiconductor device 1A includes at least one p-type back gate region 25 (in this embodiment, a plurality of p-type back gate regions 25) formed in a region differing from the drain region 17 and differing from the source region 22 in the surficial portion of the first main surface 3. The back gate regions 25 are fixed at a back gate potential. In detail, the back gate regions 25 are each formed so that a back gate potential is individually applied to the back gate regions 25 from the outside of the chip 2 and, as a result, each of the back gate regions 25 is fixed at this back gate potential. In other words, the back gate potential is given to the back gate regions 25 independently of a source potential.

In detail, the back gate regions 25 are each formed in a region differing from the source region 22 in the surficial portion of the body region 19. In more detail, the back gate regions 25 are each formed in a region on the side opposite to the drain region 17 with respect to the source region 22 in the surficial portion of the body region 19. The back gate regions 25 are each formed at a distance inwardly from the peripheral edge of the body region 19. A first back gate region 61 has a p-type impurity concentration higher than the body region 19.

In this embodiment, the back gate regions 25 are each formed in a region of a part of the body region 19 in an ended belt shape in a plan view. In detail, the back gate regions 25 are formed in the surficial portion of the first region 19A and the surficial portion of the second region 19B, respectively, and are not formed in the third region 19C and in the fourth region 19D. The back gate regions 25 each extend in an ended belt shape along the first and second regions 19A and 19B in a plan view.

In this embodiment, the back gate regions 25 are each connected to the source region 22 in the first direction X. In other words, in this embodiment, the source region 22 to which the source potential is individually given and the back gate region 25 to which the back gate potential is individually given coexist at the surficial portion of the body region 19.

Preferably, the length of each of the back gate regions 25 is equal to or less than the length of the drain region 17 with respect to the second direction Y. Of course, the single back gate region 25 having an annular shape (in detail, oval annular shape) surrounding the impurity region 15 may be formed. Also, the single or more back gate regions 25 may be formed in at least one region among the first region 19A, the second region 19B, the third region 19C, and the fourth region 19D of the body region 19.

The semiconductor device 1A includes a field insulation film 30 that selectively covers the first main surface 3 in the transistor region 9. The field insulation film 30 includes silicon oxide. In this embodiment, the field insulation film 30 is made of a LOCOS film (Local oxidation of silicon film) formed by selective oxidation of the first main surface 3. The field insulation film 30 may have a thickness of not less than 0.1 μm and not more than 2 μm. The field insulation film 30 selectively covers the first main surface 3 so as to expose the separation region 11, the drain region 17, the source region 22, and the back gate region 25.

The field insulation film 30 has a part, which covers a region between the drain region 17 and the source region 22, of the first main surface 3. In detail, the field insulation film 30 is formed in an annular shape (in this embodiment, oval annular shape) surrounding the drain region 17 so as to expose the drain region 17 and the body region 19 in a plan view. In other words, the field insulation film 30 covers the drift region 23 so as to expose the channel region 24.

Also, the field insulation film 30 has a part, which covers a region between the separation region 11 and the source region 22, of the first main surface 3. In detail, the field insulation film 30 is formed in an annular shape surrounding the body region 19 so as to expose the separation region 11, the source region 22, and the back gate region 25 in a region between the separation region 11 and the body region 19. Also, the field insulation film 30 covers a region located outside the transistor region 9 so as to expose the separation region 11 in the first main surface 3.

Referring to FIG. 2 to FIG. 4, the semiconductor device 1A includes a field electrode 31 arranged on the field insulation film 30 in the transistor region 9. The field electrode 31 may include conductive polysilicon (n-type or p-type polysilicon). In this embodiment, the field electrode 31 is made of a field resistive film electrically connected to the drain region 17 and to the back gate region 25. The field electrode 31 is electrically separated from the source region 22. The field electrode 31 forms a potential gradient toward the back gate region 25 from the drain region 17, and suppresses deflection in electric field distribution in the drift region 23.

The field electrode 31 is linearly routed around on the field insulation film 30. If a single straight line that connects the drain region 17 and the back gate region 25 in a plan view is set, the field electrode 31 linearly extends so as to cross this straight line a plurality of times. In detail, the field electrode 31 concentrically surrounds the drain region 17 a plurality of times in a plan view. In more detail, the field electrode 31 is routed around in a helical shape surrounding the drain region 17 in a plan view.

The field electrode 31 has a first end portion 32 (first portion) on the drain region 17 side, a second end portion 33 (second portion) on the back gate region 25 (body region 19) side, and a helical portion 34 that extends between the first end portion 32 and the second end portion 33. The first end portion 32 is a connection portion (electrical application end) that is electrically connected to the drain region 17 (drain potential), and the second end portion 33 is a connection portion (electrical application end) that is electrically connected to the back gate region 25 (back gate potential). In other words, the field electrode 31 is electrically separated from the source region 22 (source potential).

The arrangement of the first end portion 32 and the arrangement of the second end portion 33 are arbitrary. In this embodiment, the first end portion 32 is arranged at a position at which the first end portion 32 faces the drain region 17 in the first direction X. The first end portion 32 may face the well region 16 across the field insulation film 30. In this embodiment, the second end portion 33 is arranged at a position at which the second end portion 33 faces the source region 22 in the first direction X.

The second end portion 33 may face the impurity region 15 across the field insulation film 30. The helical portion 34 is elliptically and helically wound from the first end portion 32 toward the second end portion 33 so as to surround the drain region 17 in a plan view. The helical portion 34 faces the drift region 23 across the field insulation film 30.

The field electrode 31 forms a potential gradient from the first end portion 32 toward the second end portion 33 in the helical direction. Also, the field electrode 31 forms a potential gradient that gradually decreases in accordance with the winding pitch of the helical portion 34 from the drain region 17 toward the back gate region 25 (body region 19) with respect to a direction perpendicular to the helical direction. The field electrode 31 thins out an electric field in the drift region 23, and suppresses deflection in electric field distribution in the drift region 23.

The field electrode 31 may have a line width of not less than 1 μm and not more than 5 μm. The line width is defined by a width in a direction perpendicular to the extending direction (i.e., helical direction) of the field electrode 31. Preferably, the line width is equal to or less than 3 μm. The field electrode 31 may have a resistance value of not less than 10 MΩ and not more than 100 MΩ. The field electrode 31 may be formed with a substantially constant line width in the linear portion and in the circular arc portion. Also, for example, if the width of the drift region 23 gradually increases toward the middle of the circular arc portion, the line width of the field electrode 31 may gradually increase from the linear portion toward the middle of the circular arc portion.

The pitch of the field electrode 31 may be not less than 1 μm and not more than 10 μm. Preferably, the pitch of the field electrode 31 is equal to or more than 2 μm. The pitch of the field electrode 31 is defined by a distance (i.e., the winding pitch of the helical portion 34) between line portions that adjoin each other. The number of winding turns of the field electrode 31 may be not less than 5 and not more than 100 (preferably, not less than 25 and not more than 75).

The semiconductor device 1A includes an inner field electrode 35 arranged in a region closer to the drain region 17 than the field electrode 31 on the field insulation film 30. In this embodiment, the inner field electrode 35 is arranged in a region surrounded by the field electrode 31, and is fixed at the same potential as the drain region 17 (drain region 17). The inner field electrode 35 has substantially the same thickness as the field electrode 31, and includes the same material (i.e., conductive polysilicon) as the field electrode 31.

The inner field electrode 35 is arranged in a region between the drain region 17 and the field electrode 31 at a distance from the drain region 17 and from the field electrode 31 in a plan view. In this embodiment, the inner field electrode 35 is formed in an annular shape (in detail, oval annular shape) surrounding the drain region 17. The inner field electrode 35 may face the well region 16 across the field insulation film 30.

The inner field electrode 35 includes an inner edge portion 35a and an outer edge portion 35b. Preferably, the inner edge portion 35a is formed at a substantially constant distance from the drain region 17. Preferably, the outer edge portion 35b is formed at a substantially constant distance from the field electrode 31. Preferably, the distance between the inner field electrode 35 and the field electrode 31 is equal to the pitch of the field electrode 31.

In this embodiment, the inner field electrode 35 is formed with a non-constant width along a circumferential direction. In detail, the inner field electrode 35 has a field projection portion 35c in the outer edge portion 35b. The field projection portion 35c projects toward the field electrode 31 so as to come close to a front end of the first end portion 32 of the field electrode 31. The field projection portion 35c holds the distance between the inner field electrode 35 and the field electrode 31 so as to be substantially constant, and suppresses static deflection caused by the first end portion 32 of the field electrode 31.

In this embodiment, the field projection portion 35c is connected to the first end portion 32 of the field electrode 31, and is fixed at the same potential as this first end portion 32. The inner field electrode 35 is not necessarily required to be connected to the first end portion 32 as far as the first end portion 32 is fixed at the same potential as the first end portion 32. Therefore, the field projection portion 35c may face the front end of the first end portion 32 in the helical direction of the field electrode 31. Also, the presence or absence of the inner field electrode 35 is arbitrary, and may be removed if necessary.

The width of the inner field electrode 35 may be not less than 1 μm and not more than 15 μm. Preferably, the inner field electrode 35 is formed wider than the field electrode 31. Preferably, the width of the inner field electrode 35 is not less than 1.5 times and not more than 5 times as wide as the width of the field electrode 31. Of course, the inner field electrode 35 having a width equal to or less than the line width of the field electrode 31 may be formed.

The semiconductor device 1A includes a gate insulation film 36 covering the channel region 24 on the first main surface 3. The gate insulation film 36 has a thickness less than the thickness of the field insulation film 30, and is connected to the field insulation film 30. The thickness of the gate insulation film 36 may be not less than 10 nm and not more than 200 nm.

The gate insulation film 36 may include a silicon oxide film. The gate insulation film 36 is formed in a belt shape extending along the channel region 24 in a plan view. In this embodiment, the gate insulation film 36 is formed in an annular shape (in detail, oval annular shape) surrounding the field insulation film 30 in a plan view, and covers the drift region 23, the body region 19, and the source region 22.

The semiconductor device 1A includes a gate electrode 37 arranged on the gate insulation film 36. The gate electrode 37 has a thickness substantially equal to that of the field electrode 31, and may include the same material (i.e., conductive polysilicon) as the field electrode 31. The gate electrode 37 may include either one or both of an n-type region and a p-type region in the conductive polysilicon. The gate electrode 37 faces the drift region 23 and the channel region 24 across the gate insulation film 36.

The gate electrode 37 is formed in a belt shape extending along the channel region 24 in a plan view. In this embodiment, the gate electrode 37 is formed in an annular shape (in detail, oval annular shape) surrounding the field insulation film 30 in a plan view. The gate electrode 37 has a lead-out portion 38 led out from on a surface of the gate insulation film 36 onto the field insulation film 30. The lead-out portion 38 is formed in an annular shape (in detail, oval annular shape) surrounding the field electrode 31 at a distance from the field electrode 31.

The lead-out portion 38 faces the drift region 23 across the field insulation film 30. Preferably, the lead-out portion 38 is formed at a substantially constant distance from the field electrode 31. Preferably, the distance between the lead-out portion 38 and the field electrode 31 is equal to the pitch of the field electrode 31.

The gate electrode 37 includes an inner edge portion 37a and an outer edge portion 37b. The inner edge portion 37a is formed by the lead-out portion 38. The outer edge portion 37b is formed in a region that coincides with the body region 19 in a plan view. Preferably, the outer edge portion 37b is formed at a substantially constant distance from the outer edge portion 35b of the field insulation film 30.

In this embodiment, the gate electrode 37 is formed with a non-constant width along a circumferential direction. In detail, the gate electrode 37 has a gate projection portion 37c that projects to the drain region 17 side in the outer edge portion 37b (lead-out portion 38). The gate projection portion 37c projects toward the field electrode 31 so as to come close to a front end of the second end portion 33 in the helical direction of the field electrode 31.

The gate projection portion 37c faces the front end of the second end portion 33 in the helical direction of the field electrode 31. The gate projection portion 37c holds the distance between the gate electrode 37 and the field electrode 31 so as to be substantially constant, and suppresses static deflection caused by the second end portion 33 of the field electrode 31.

Referring to FIG. 4, the semiconductor device 1A includes an insulation layer 40 covering the device regions 8 on the first main surface 3. The insulation layer 40 has a laminated structure in which a plurality of interlayer insulation films 41 are laminated. The number of laminated layers of the interlayer insulation films 41 is arbitrary, and is not limited to a specific numerical value. The insulation layer 40 may include three or more interlayer insulation films 41. A first interlayer insulation film 41A and a second interlayer insulation film 41B among the interlayer insulation films 41 are shown in FIG. 4.

The first interlayer insulation film 41A covers the first main surface 3, and the second interlayer insulation film 41B covers the first interlayer insulation film 41A. Each of the interlayer insulation films 41 includes at least one of a silicon oxide film and a silicon nitride film. Each of the interlayer insulation films 41 may have a single layer structure consisting of a silicon oxide film or a silicon nitride film. Each of the interlayer insulation films 41 may have a laminated structure in which at least one silicon oxide film and at least one silicon nitride film are laminated in an arbitrary order.

The semiconductor device 1A includes a drain wiring 42 selectively routed around in the insulation layer 40 so as to be electrically connected to the drain region 17 and to the first end portion 32 of the field electrode 31. The drain wiring 42 gives a drain potential to the drain region 17 and to the first end portion 32 of the field electrode 31. The drain wiring 42 forms a multi-layer wiring in the insulation layer 40.

In this embodiment, the drain wiring 42 includes a first drain wiring 43, a second drain wiring 44, a first drain via electrode 45, and a second drain via electrode 46. The first drain wiring 43 integrally includes a first drain wiring 43A on the drain region 17 side and a first drain wiring 43B on the first end portion 32 side of the field electrode 31. Of course, the first drain wiring 43A and the first drain wiring 43B may be arranged at a distance from each other as far as these wirings 43A and 43B are fixed at the same potential.

The first drain wiring 43 is arranged on the first interlayer insulation film 41A so as to face the drain region 17, the first end portion 32 of the field electrode 31, and the inner field electrode 35 in a cross-sectional view. Preferably, the first drain wiring 43 faces the whole area of the drain region 17, the whole area of the first end portion 32, and the whole area of the inner field electrode 35 in a cross-sectional view.

The second drain wiring 44 is arranged on the second interlayer insulation film 41B so as to face the first drain wiring 43 in a cross-sectional view. Preferably, the second drain wiring 44 is led out to a position at which the second drain wiring 44 faces the inner field electrode 35 in a cross-sectional view. Preferably, the second drain wiring 44 is led out to a position at which the second drain wiring 44 faces the first end portion 32 of the field electrode 31 in a cross-sectional view. Particularly preferably, the second drain wiring 44 is led out to a position at which the second drain wiring 44 faces the helical portion 34 of the field electrode 31 in a cross-sectional view. The second drain wiring 44 may have a thickness exceeding the thickness of the first drain wiring 43.

The first drain via electrode 45 is interposed in a region between the drain region 17 and the first drain wiring 43, and electrically connects the drain region 17 to the first drain wiring 43. Also, the first drain via electrode 45 is interposed in a region between the first end portion 32 of the field electrode 31 and the first drain wiring 43, and electrically connects the first end portion 32 to the first drain wiring 43.

Of course, the first drain via electrode 45 may be interposed in a region between the inner field electrode 35 and the first drain wiring 43, and may electrically connect the inner field electrode 35 to the first drain wiring 43. The second drain via electrode 46 is interposed in a region between the first drain wiring 43 and the second drain wiring 44, and electrically connects the first drain wiring 43 to the second drain wiring 44.

The semiconductor device 1A includes a source wiring 47 that is at a distance from the drain wiring 42 and that is selectively routed around in the insulation layer 40 so as to be electrically connected to the source region 22. The source wiring 47 gives a source potential to the source region 22. The source wiring 47 is electrically separated from the back gate region 25. Also, the source wiring 47 is electrically separated from the separation region 11. The source wiring 47 forms a multi-layer wiring in the insulation layer 40.

In detail, the source wiring 47 includes a first source wiring 48, a second source wiring 49, a first source via electrode 50, and a second source via electrode 51. The first source wiring 48 is arranged on the first interlayer insulation film 41A so as to face the source region 22 in a cross-sectional view. Preferably, the first source wiring 48 faces the whole area of the source region 22 in a cross-sectional view. Preferably, the first source wiring 48 does not face the back gate region 25 in a cross-sectional view.

The second source wiring 49 is arranged on the second interlayer insulation film 41B so as to face the first source wiring 48 in a cross-sectional view. Preferably, the second source wiring 49 covers the whole area of the source region 22 in a cross-sectional view. Preferably, the second source wiring 49 is led out to a position at which the second source wiring 49 crosses the gate electrode 37 in a cross-sectional view and at which the second source wiring 49 faces the second end portion 33 of the inner field electrode 35. Particularly preferably, the second source wiring 49 is led out to a position at which the second source wiring 49 faces the helical portion 34 of the inner field electrode 35 in a cross-sectional view. The second source wiring 49 may have a thickness exceeding the thickness of the first source wiring 48.

The first source via electrode 50 is interposed in a region between the source region 22 and the first source wiring 48, and electrically connects the source region 22 to the first source wiring 48. The second source via electrode 51 is interposed in a region between the first source wiring 48 and the second source wiring 49, and electrically connects the first source wiring 48 to the second source wiring 49.

The semiconductor device 1A includes a back gate wiring 52 that is at a distance from the drain wiring 42 and from the source wiring 47 and that is selectively routed around in the insulation layer 40 so as to be electrically connected to the back gate region 25 and to the second end portion 33 of the field electrode 31. In this embodiment, the back gate wiring 52 is also electrically connected to the separation region 11. The back gate wiring 52 is electrically separated from the source region 22. The back gate wiring 52 forms a multi-layer wiring in the insulation layer 40.

In detail, the back gate wiring 52 includes a first back gate wiring 53, a second back gate wiring 54, a first back gate via electrode 55, and a second back gate via electrode 56. The first back gate wiring 53 integrally includes a first back gate wiring 53A on the back gate region 25 side, a first back gate wiring 53B on the second end portion 33 side of the field electrode 31, and a first back gate wiring 53C on the separation region 11 side. Of course, the first back gate wiring 53A, the first back gate wiring 53B, and the first back gate wiring 53C may be arranged at a distance from each other as far as these back gate wirings are fixed at the same potential.

The first back gate wiring 53 is formed on the first interlayer insulation film 41A at a distance from the source region 22. The first back gate wiring 53 faces the back gate region 25, the second end portion 33 of the field electrode 31, and the separation region 11 in a cross-sectional view. Preferably, the first back gate wiring 53 faces the whole area of the back gate region 25 in a cross-sectional view. The first back gate wiring 53 may face the helical portion 34 of the field electrode 31. The first back gate wiring 53 may be led out to a region located outside the transistor region 9 in a plan view.

In this embodiment, the second back gate wiring 54 is arranged on the second interlayer insulation film 41B so as to face the first back gate wiring 53 in the region located outside the transistor region 9 in a plan view. Of course, the second back gate wiring 54 may be arranged so as to face the first back gate wiring 53 in the transistor region 9 in a plan view. The second back gate wiring 54 may have a thickness exceeding the thickness of the first back gate wiring 53.

The first back gate via electrode 55 is interposed in a region between the back gate region 25 and the first back gate wiring 53, and electrically connects the back gate region 25 to the first back gate wiring 53. Also, the first back gate via electrode 55 is interposed in a region between the second end portion 33 of the field electrode 31 and the first back gate wiring 53, and electrically connects the second end portion 33 of the field electrode 31 to the first back gate wiring 53.

Also, the first back gate via electrode 55 is interposed in a region between the separation region 11 and the first back gate wiring 53, and electrically connects the separation region 11 to the first back gate wiring 53. The second back gate via electrode 56 is interposed in a region between the first back gate wiring 53 and the second back gate wiring 54, and electrically connects the first back gate wiring 53 to the second back gate wiring 54.

The semiconductor device 1A includes a gate wiring 57 that is at a distance from the drain wiring 42, from the source wiring 47, and from the back gate wiring 52 and that is selectively routed around in the insulation layer 40 so as to be electrically connected to the gate electrode 37. The gate wiring 57 gives a gate potential to the gate electrode 37. The gate wiring 57 forms a multi-layer wiring in the insulation layer 40.

In detail, the gate wiring 57 includes a first gate wiring 58, a second gate wiring (not shown), a first gate via electrode 59, and a second gate via electrode (not shown). The first gate wiring 58 is arranged on the first interlayer insulation film 41A so as to face the gate electrode 37 in a cross-sectional view.

The first gate wiring 58 is led out to a region located outside the transistor region 9 in a plan view. In this embodiment, the second gate wiring (not shown) is arranged on the second interlayer insulation film 41B so as to face the first gate wiring 58 in the region located outside the transistor region 9 in a plan view. The second gate wiring may have a thickness exceeding the thickness of the first gate wiring 58.

The first gate via electrode 59 is interposed in a region between the gate electrode 37 and the first gate wiring 58, and electrically connects the gate electrode 37 to the first gate wiring 58. The second gate via electrode (not shown) is interposed in a region between the first gate wiring 58 and the second gate wiring, and electrically connects the first gate wiring 58 to the second gate wiring.

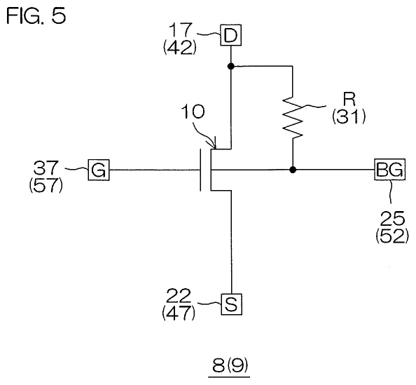

FIG. 5 is a circuit diagram showing an electric structure (FET structure 10 and field electrode 31) in the transistor region 9. Referring to FIG. 5, the semiconductor device 1A includes the FET structure 10 and a resistor R in the transistor region 9. The FET structure 10 includes a drain D (drain region 17), a source S (source region 22), a back gate BG (back gate region 25), and a gate G (gate insulation film 36 and gate electrode 37).

The resistor R consists of the field electrode 31, and is electrically connected to the drain D and the back gate BG. The resistor R is not connected to the drain D and the source S. The resistor R is not connected to the drain D and the gate G. The resistor R is not connected to the source S and the gate G of the FET structure 10.

In this embodiment, only the FET structure 10 and the resistor R are formed in the transistor region 9. In other words, other functional devices connected between the drain D and the source S are not formed in the transistor region 9. Also, other functional devices connected between the drain D and the gate G are not formed in the transistor region 9. Also, other functional devices connected between the source S and the gate G are not formed in the transistor region 9.

In the FET structure 10, a drain potential, a source potential, a back gate potential, and a gate potential are given to the drain D (drain region 17), the source S (source region 22), the back gate BG (back gate region 25), and the gate G (gate electrode 37), respectively, from a region located outside the transistor region 9 (which includes a region located outside the semiconductor device 1A). In other words, the FET structure 10 is configured so that a source potential is individually given to the source S (source region 22) and so that a back gate potential is individually given to the back gate BG (back gate region 25).

The drain potential may be a power source potential. The source potential is equal to or less than the drain potential. The source potential may be a reference potential, a ground potential, or a potential other than these potentials. The back gate potential is equal to or less than the drain potential. The back gate potential may be a reference potential, a ground potential, or a potential other than these potentials. The back gate potential is not hindered from becoming equal in potential to the source potential. In other words, the back gate region 25 is electrically separated from the source region 22 within the chip 2, whereas the back gate region 25 may be fixed at the same potential as the source region 22 by potential control from the outside.

As described above, the semiconductor device 1A includes the chip 2, the n-type drain region 17, the n-type source region 22, the p-type back gate region 25, the gate insulation film 36, and the gate electrode 37. The chip 2 has the first main surface 3. The drain region 17 is formed in the surficial portion of the first main surface 3. The source region 22 is formed in a region differing from the drain region 17 in the surficial portion of the first main surface 3.

The back gate region 25 is formed in a region differing from the drain region 17 and differing from the source region 22 in the surficial portion of the first main surface 3. The back gate region 25 is electrically separated from the drain region 17 and from the source region 22. The gate insulation film 36 covers the source region 22. The gate electrode 37 faces the source region 22 across the gate insulation film 36.

This structure makes it possible to give a source potential electrically independent of the back gate region 25 to the source region 22, and makes it possible to give a back gate potential electrically independent of the source region 22 to the back gate region 25. Hence, it is possible to provide the semiconductor device 1A having a novel configuration capable of finely adjusting a gate threshold voltage Vth by finely adjusting a source potential.

In the thus-formed structure, preferably, the semiconductor device 1A includes the field insulation film 30 and the field electrode 31. The field insulation film 30 covers a region between the drain region 17 and the source region 22 on the first main surface 3. The field electrode 31 is arranged on the field insulation film 30. This structure makes it possible to finely adjust a gate threshold voltage Vth in a structure including the field insulation film 30 and the field electrode 31.

In this case, preferably, the field electrode 31 is electrically separated from the source region 22. This structure makes it possible to give a source potential electrically independent of the field electrode 31 to the source region 22. Hence, it is possible to prevent the potential of the field electrode 31 from acting on the source region 22.

In this case, preferably, the field electrode 31 is electrically connected to the drain region 17 and the back gate region 25. With this structure, a potential difference between the potential of the drain region 17 and the potential of the back gate region 25 is generated in the field electrode 31. Hence, it is possible to adjust electric field distribution between the drain region 17 and the back gate region 25 by means of the field electrode 31 while keeping the independence of the source potential given to the source region 22.

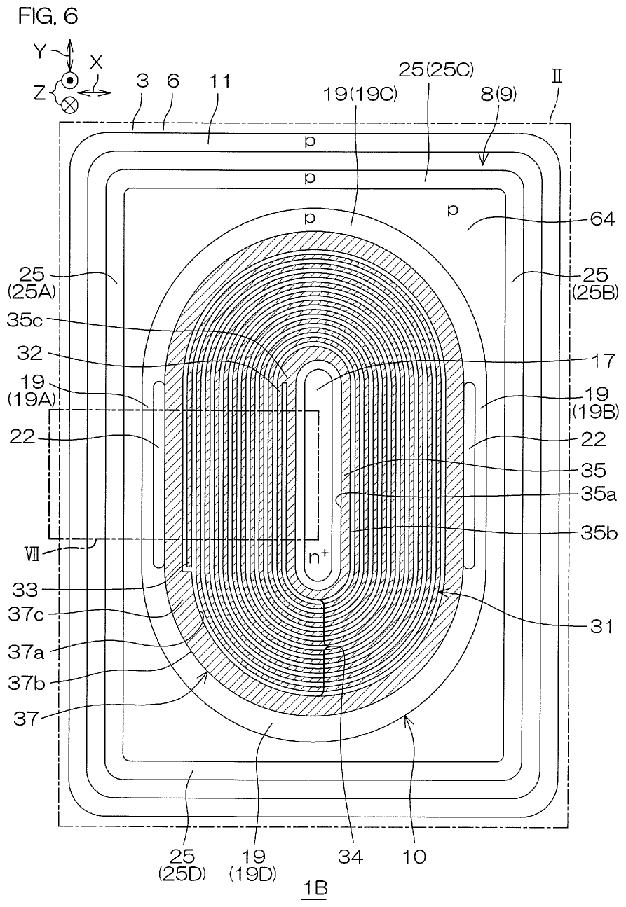

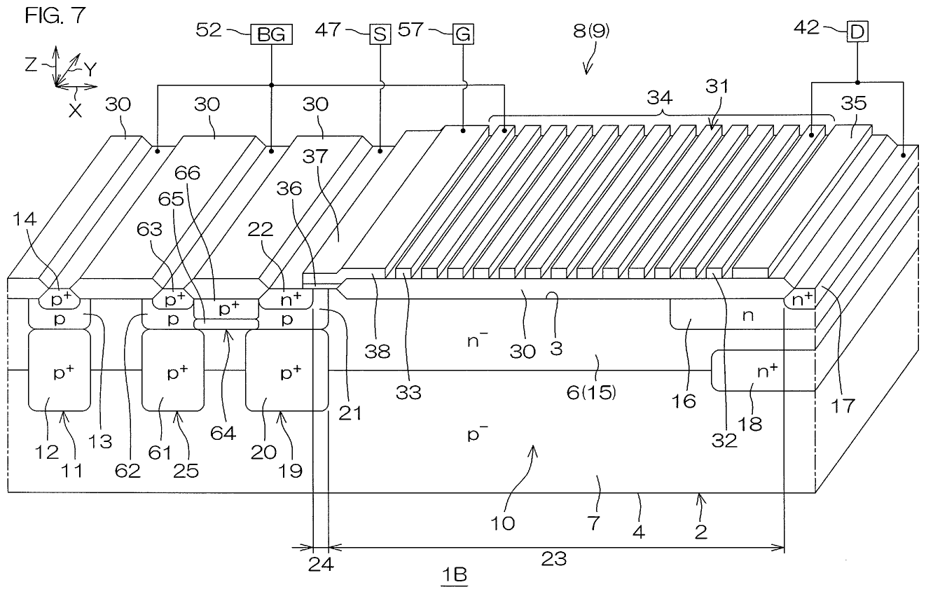

FIG. 6 is an enlarged plan view corresponding to FIG. 2 and showing a semiconductor device 1B according to a second embodiment. FIG. 7 is a cross-sectional perspective view of region VII shown in FIG. 6. Referring to FIG. 6 and FIG. 7, the semiconductor device 1B has a form obtained by modifying the semiconductor device 1A.

In detail, the semiconductor device 1B does not include the back gate region 25 in the surficial portion of the body region 19, and include only the source regions 22. The source regions 22 are formed in the same form as in the first embodiment.

The semiconductor device 1B includes the p-type back gate region 25 that is at a distance from the drain region 17 and from the source region 22 in the transistor region 9 and that is formed in the surficial portion of the first main surface 3. In detail, the back gate region 25 is formed in a region between the separation region 11 and the body region 19 at a distance from the separation region 11 and from the body region 19. In this embodiment, the back gate region 25 extends from the first main surface 3 toward the second semiconductor region 7 in a wall shape so as to cross the impurity region 15, and is electrically connected to the second semiconductor region 7.

In this embodiment, the back gate region 25 includes the first back gate region 61, a second back gate region 62, and a third back gate region 63. The first back gate region 61 is formed in a boundary portion between the second semiconductor region 7 and the impurity region 15. The first back gate region 61 is formed at a distance from the first and second main surfaces 3 and 4 in the normal direction Z, and is electrically connected to the second semiconductor region 7. The first back gate region 61 has a p-type impurity concentration higher than the second semiconductor region 7.

The second back gate region 62 is formed in a region between the first main surface 3 and the first back gate region 61 in the impurity region 15, and is electrically connected to the first back gate region 61. The second back gate region 62 may have a p-type impurity concentration lower than the first back gate region 61. The third back gate region 63 is formed in a surficial portion of the second back gate region 62, and is exposed from the first main surface 3. The third back gate region 63 may have a p-type impurity concentration higher than the second back gate region 62.

In this embodiment, the back gate region 25 is formed in an annular shape surrounding the body region 19 in a plan view and has a part extending in the first direction X and a part extending in the second direction Y. In this embodiment, the back gate region 25 is formed in a quadrangular annular shape (in detail, rectangular annular shape extending in the second direction Y) in a plan view. In other words, in this embodiment, the back gate region 25 has a planar shape matching the planar shape of the separation region 11 in a plan view, whereas the back gate region 25 has a planar shape not matching the planar shape of the body region 19 in a plan view.

In detail, the back gate region 25 includes a first region 25A, a second region 25B, a third region 25C, and a fourth region 25D in a plan view. The first to fourth regions 25A to 25D of the back gate region 25 are formed by the first back gate region 61, the second back gate region 62, and the third back gate region 63.

The first region 25A is a part extending in the second direction Y in a belt shape at a distance from the first region 19A of the body region 19 toward one side in the first direction X in a plan view. The second region 25B is a part extending in the second direction Y in a belt shape at a distance from the second region 19B of the body region 19 toward the other side in the first direction X in a plan view. The second region 25B extends in parallel with the first region 25A in a plan view, and faces the first region 25A across the drain region 17 (well region 16) in the first direction X. The length of the first region 25A and the length of the second region 25B may exceed the length of the drain region 17 with respect to the second direction Y.

The third region 25C is a part extending in the first direction X in a linear belt shape so as to connect an end portion of the first region 25A and an end portion of the second region 25B in a plan view. The fourth region 25D is a part extending in the first direction X in a linear belt shape so as to connect the other end portion of the first region 25A and the other end portion of the second region 25B in a plan view.

The back gate region 25 may have a planar shape matching the planar shape of the body region 19. In other words, the third region 25C of the back gate region 25 may extend in a circular-arc belt shape along the third region 19C of the body region 19 in a plan view. Also, the fourth region 25D of the back gate region 25 may extend in a circular-arc belt shape along the fourth region 19D of the body region 19 in a plan view.

The semiconductor device 1B includes a p-type surficial region 64 formed in a region between the body region 19 and the back gate region 25 in the surficial portion of the first main surface 3. The surficial region 64 is formed at a distance from the bottom portion of the impurity region 15 toward the first main surface 3 side. In other words, the surficial region 64 is formed more shallowly than the body region 19 and the back gate region 25, and is not connected to the second semiconductor region 7. The surficial region 64 may be formed more shallowly than the second body region 21 and the second back gate region 62.

The surficial region 64 may be connected to either one or both of the body region 19 and the back gate region 25. In this embodiment, the surficial region 64 is formed in the whole area of a region between the body region 19 and the back gate region 25, and is connected to both of the body region 19 and the back gate region 25. In this embodiment, the surficial region 64 is connected to the source region 22 and to the back gate region 25. The surficial region 64 suppresses channel inversion in a region between the body region 19 and the back gate region 25.

In this embodiment, the surficial region 64 includes a first surficial region 65 and a second surficial region 66. The first surficial region 65 has a p-type impurity concentration higher than the second body region 21, and is formed in the surficial portion of the first main surface 3. The first surficial region 65 may have a p-type impurity concentration higher than the second back gate region 62. The first surficial region 65 is connected to the second body region 21 and to the second back gate region 62. In this embodiment, the first surficial region 65 is connected to the source region 22 in the second body region 21 (body region 19), and is connected to the third back gate region 63 in the second back gate region 62.

The second surficial region 66 has a p-type impurity concentration less than the first surficial region 65, and is formed in a region between the first surficial region 65 and the bottom side (second principal surface 4 side) of the first semiconductor region 6. The second surficial region 66 is connected to the second body region 21 and to the second back gate region 62. The second surficial region 66 may have a p-type impurity concentration substantially equal to that of the second body region 21 and/or that of the third back gate region 63.

The second surficial region 66 may be formed by use of a part of the second body region 21 and/or a part of the third back gate region 63. In other words, the second surficial region 66 may be formed integrally with either one or both of the second body region 21 and the third back gate region 63.

In this embodiment, the field insulation film 30 has a part that covers a region between the source region 22 and the back gate region 25 in the first main surface 3. In detail, the field insulation film 30 is formed in an annular shape surrounding the source region 22 (body region 19) so as to cover the whole area of the surficial region 64 and so as to expose the source region 22 and the back gate region 25 in a plan view.

Also, the field insulation film 30 has a part that covers a region between the separation region 11 and the back gate region 25 in the first main surface 3. In detail, the field insulation film 30 is formed in an annular shape surrounding the back gate region 25 so as to expose the separation region 11 and the back gate region 25.

The drain wiring 42 has the same form as in the first embodiment, and is electrically connected to the drain region 17 and to the first end portion 32 of the field electrode 31. The source wiring 47 has the same form as in the first embodiment, and is electrically connected to the source region 22. The back gate wiring 52 has the same form as in the first embodiment, and is electrically connected to the separation region 11, to the back gate region 25, and to the second end portion 33 of the field electrode 31. The gate wiring 57 has the same form as in the first embodiment, and is electrically connected to the gate electrode 37.

The same effect as fulfilled by the semiconductor device 1A described above is fulfilled also by the semiconductor device 1B. With the semiconductor device 1B, the back gate region 25 is formed at a distance from the source region 22 (body region 19). Therefore, this structure makes it possible to suppress the action of the source potential on the back gate region 25, and suppress the action of the back gate potential on the source region 22. Therefore, it is possible to stably give the source potential to the source region 22, and it is possible to stably give the back gate potential to the back gate region 25.

The embodiments have been described as above, and yet the present invention can be embodied in still other modes. For example, the field electrode 31 consisting of a field resistive film is shown as described in each of the aforementioned embodiments. However, the field electrode 31 may be employed that is electrically separated from the drain region 17, from the source region 22, and from the back gate region 25 and that does not function as a field resistive film. In this case, the field electrode 31 may be formed so as to be in an electrically floating state.

The well region 16 that extends in the second direction Y in a belt shape in a plan view is formed as described in each of the aforementioned embodiments. However, the well region 16 may be formed in an annular shape (for example, oval annular shape extending in the second direction Y) in a plan view. In this case, the drain region 17 may be formed in an annular shape (oval annular shape) extending along the well region 16 in a plan view.

The first conductivity type is an n-type, and the second conductivity type is a p-type as described in each of the aforementioned embodiments. However, the first conductivity type may be a p-type, and the second conductivity type may be an n-type. A concrete configuration in this case can be obtained by replacing the n-type region with the p-type region and by replacing the p-type region with the n-type region in the foregoing description and in the accompanying drawings.

Characteristic examples extracted from this description and from the drawings are hereinafter shown. A semiconductor device having a novel configuration is hereinafter provided. Hereinafter, alphanumeric characters etc., in parentheses represent corresponding components etc., in the aforementioned embodiments, and yet this representation does not denote that the scope of each clause is limited to the embodiments.

[A1] A semiconductor device (1A, 1B) comprising: a chip (2) having a main surface (3); a first conductivity type (n-type) drain region (17) formed in a surficial portion of the main surface (3); a first conductivity type (n-type) source region (22) formed in a region differing from the drain region (17) in the surficial portion of the main surface (3); a second conductivity type (p-type) back gate region (25) formed in a region differing from the drain region (17) and from the source region (22) in the surficial portion of the main surface (3) so as to be electrically separated from the drain region (17) and from the source region (22); a gate insulation film (36) covering the source region (22) on the main surface (3); and a gate electrode (37) formed on the gate insulation film (36).

[A2] The semiconductor device (1A, 1B) according to A1, further comprising: a field insulation film (30) covering a region between the drain region (17) and the source region (22) on the main surface (3); and a field electrode (31) arranged on the field insulation film (30).

[A3] The semiconductor device (1A, 1B) according to A2, wherein the field electrode (31) is electrically separated from the source region (22).

[A4] The semiconductor device (1A, 1B) according to A2 or A3, wherein the field electrode (31) consists of a field resistive film (31).

[A5] The semiconductor device (1A, 1B) according to any one of A2 to A4, wherein the field electrode (31) is electrically connected to the drain region (17) and to the back gate region (25).

[A6] The semiconductor device (1A, 1B) according to any one of A2 to A5, wherein the field electrode (31) is helically formed so as to surround the drain region (17) as viewed in plan.

[A7] The semiconductor device (1A, 1B) according to any one of A2 to A6, wherein the gate insulation film (36) is connected to the field insulation film (30), and the gate electrode (37) has a lead-out portion (38) led out from on a surface of the gate insulation film (36) onto the field insulation film (30).

[A8] The semiconductor device (1A, 1B) according to any one of A1 to A7, further comprising: a second conductivity type (p-type) separation region (11) formed in the surficial portion of the main surface (3) so as to divisionally form a device region (8, 9) in the main surface (3); wherein the drain region (17), the source region (22), and the back gate region (25) are formed in the device region (8, 9).

[A9] The semiconductor device (1A, 1B) according to A8, wherein the separation region (11) is electrically separated from the source region (22).

[A10] The semiconductor device (1A, 1B) according to A8 or A9, wherein the separation region (11) is fixed at a same potential as the back gate region (25).

[A11] The semiconductor device (1A, 1B) according to any one of A8 to A10, wherein the separation region (11) is formed in an annular shape surrounding a part of the main surface (3) as viewed in plan.

[A12] The semiconductor device (1A, 1B) according to any one of A1 to A11, further comprising: a drain wiring (42) that is arranged on the main surface (3) and that is electrically connected to the drain region (17); a source wiring (47) that is arranged on the main surface (3) and that is electrically connected to the source region (22); and a back gate wiring (52) that is arranged on the main surface (3) and that is electrically connected to the back gate region (25).

[A13] The semiconductor device (1A, 1B) according to A12, wherein the back gate wiring (52) is arranged at a distance from the drain wiring (42) and from the source wiring (47), and is electrically separated from the drain wiring (42) and from the source region (22).

[A14] The semiconductor device (1A, 1B) according to A12 or A13, wherein the drain wiring (42) faces the drain region (17) in a cross-sectional view, the source wiring (47) faces the source region (22) in a cross-sectional view, and the back gate wiring (52) faces the back gate region (25), and does not face the source region (22) in a cross-sectional view.

[A15] The semiconductor device (1A, 1B) according to any one of A1 to A14, wherein the drain region (17) is formed in a belt shape or an annular shape extending in a single direction as viewed in plan, the source region (22) is formed in a belt shape extending in the single direction as viewed in plan, and the back gate region (25) is formed in a belt shape extending in the single direction as viewed in plan.

[A16] The semiconductor device (1A, 1B) according to any one of A1 to A15, further comprising: a first conductivity type (n-type) well region (16) formed in the surficial portion of the main surface (3); wherein the drain region (17) is formed in the well region (16).

[A17] The semiconductor device (1A, 1B) according to any one of A1 to A16, further comprising: a first conductivity type (n-type) embedded region (18) formed at a distance from the drain region (17) in a thickness direction of the chip (2).

[A18] The semiconductor device (1A, 1B) according to any one of A1 to A17, further comprising: a second conductivity type (p-type) body region (19) formed in the surficial portion of the main surface (3) at a distance from the drain region (17); wherein the source region (22) is formed in the body region (19), and the back gate region (25) is formed in a region differing from the source region (22) in the body region (19).

[A19] The semiconductor device (1A, 1B) according to any one of A1 to A17, further comprising: a second conductivity type (p-type) body region (19) formed in the surficial portion of the main surface (3) at a distance from the drain region (17); wherein the source region (22) is formed in the body region (19), and the back gate region (25) is formed outside the body region (19).

[B1] A semiconductor device (1A, 1B) comprising: a semiconductor chip (2); a transistor structure (10) that has a drain (D, 17), a source (S, 22), a gate (G, 36, 37), and a back gate (BG, 25) and that is formed in the semiconductor chip (2) so that a source potential is individually given to the source (S, 22) and so that a back gate potential is individually given to the back gate (BG, 25); and a resistor (R, 31) arranged on the semiconductor chip (2) so as to be electrically separated from the source (S, 22) and so as to be electrically connected to the drain (D, 17) and to the back gate (BG, 25).

[B2] The semiconductor device (1A, 1B) according to B1, further comprising: a device region (8, 9) provided in the semiconductor chip (2); wherein the transistor structure (10) is formed in the device region (8, 9), and the resistor (R, 31) is arranged in the device region (8, 9).

[B3] The semiconductor device (1A, 1B) according to B1 or B2, further comprising: a source wiring (47) arranged on the semiconductor chip (2) so as to individually give the source potential to the source (S, 22); and a back gate wiring (52) arranged on the semiconductor chip (2) at a distance from the source wiring (47) so as to individually give the back gate potential to the back gate (BG, 25).

Although the embodiments of the present invention have been described in detail, these embodiments are merely concrete examples used to clarify the technical contents of the present invention, and the present invention should not be understood by being limited to these concrete examples, and the scope of the present invention is limited solely by the appended Claims.

What is claimed is:

1. A semiconductor device comprising:
a chip having a main surface;
a first conductivity type drain region formed in a surficial portion of the main surface;
a first conductivity type source region formed in a region differing from the drain region in the surficial portion of the main surface;
a second conductivity type back gate region formed in a region differing from the drain region and from the source region in the surficial portion of the main surface so as to be electrically separated from the drain region and from the source region;
a gate insulation film covering the source region on the main surface; and
a gate electrode formed on the gate insulation film.

2. The semiconductor device according to claim 1, further comprising:
a field insulation film covering a region between the drain region and the source region on the main surface; and
a field electrode arranged on the field insulation film.

3. The semiconductor device according to claim 2,
wherein the field electrode is electrically separated from the source region.

4. The semiconductor device according to claim 2,
wherein the field electrode consists of a field resistive film.

5. The semiconductor device according to claim 2,
wherein the field electrode is electrically connected to the drain region and to the back gate region.

6. The semiconductor device according to claim 2,
wherein the field electrode is helically formed so as to surround the drain region as viewed in plan.

7. The semiconductor device according to claim 2,
wherein the gate insulation film is connected to the field insulation film, and
the gate electrode has a lead-out portion led out from on a surface of the gate insulation film onto the field insulation film.

8. The semiconductor device according to claim 1, further comprising:
a second conductivity type separation region formed in the surficial portion of the main surface so as to divisionally form a device region in the main surface;
wherein the drain region, the source region, and the back gate region are formed in the device region.

9. The semiconductor device according to claim 8,
wherein the separation region is electrically separated from the source region.

10. The semiconductor device according to claim 8,
wherein the separation region is fixed at a same potential as the back gate region.

11. The semiconductor device according to claim 8,
wherein the separation region is formed in an annular shape surrounding a part of the main surface as viewed in plan.

12. The semiconductor device according to claim 1, further comprising:
a drain wiring that is arranged on the main surface and that is electrically connected to the drain region;
a source wiring that is arranged on the main surface and that is electrically connected to the source region; and
a back gate wiring that is arranged on the main surface and that is electrically connected to the back gate region.

13. The semiconductor device according to claim 12,
wherein the back gate wiring is arranged at a distance from the drain wiring and from the source wiring, and is electrically separated from the drain wiring and from the source region.

14. The semiconductor device according to claim 12,
wherein the drain wiring faces the drain region in a cross-sectional view,
the source wiring faces the source region in a cross-sectional view, and
the back gate wiring faces the back gate region, and does not face the source region in a cross-sectional view.

15. The semiconductor device according to claim 1,
wherein the drain region is formed in a belt shape or an annular shape extending in a single direction as viewed in plan,
the source region is formed in a belt shape extending in the single direction as viewed in plan, and
the back gate region is formed in a belt shape extending in the single direction as viewed in plan.

16. The semiconductor device according to claim 1, further comprising:
a first conductivity type well region formed in the surficial portion of the main surface;
wherein the drain region is formed in the well region.

17. The semiconductor device according to claim 1, further comprising:
a first conductivity type embedded region formed at a distance from the drain region in a thickness direction of the chip.

18. The semiconductor device according to claim 1, further comprising:
a second conductivity type body region formed in the surficial portion of the main surface at a distance from the drain region;
wherein the source region is formed in the body region, and
the back gate region is formed in a region differing from the source region in the body region.

19. The semiconductor device according to claim 1, further comprising:
a second conductivity type body region formed in the surficial portion of the main surface at a distance from the drain region;
wherein the source region is formed in the body region, and
the back gate region is formed outside the body region.

20. A semiconductor device comprising:
a semiconductor chip;
a transistor structure that has a drain, a source, a gate, and a back gate and that is formed in the semiconductor chip so that a source potential is individually given to the source and so that a back gate potential is individually given to the back gate; and
a resistor arranged on the semiconductor chip so as to be electrically separated from the source and so as to be electrically connected to the drain and to the back gate.
